(19) United States
(12) Patent Application Publication
(10) Pub. No.: US 2022/0122858 A1
(43) Pub. Date: Apr. 21, 2022

(54) METHOD OF MANUFACTURING SEMICONDUCTOR DEVICE AND APPARATUS FOR MANUFACTURING SEMICONDUCTOR DEVICE

(71) Applicant: KOKUSAI ELECTRIC CORPORATION, Tokyo (JP)

(72) Inventors: Hitoshi MURATA, Toyama-shi (JP); Yasuo KUNII, Toyama-shi (JP); Masaaki UENO, Toyama-shi (JP)

(73) Assignee: KOKUSAI ELECTRIC CORPORATION, Tokyo (JP)

(21) Appl. No.: 17/563,469

(22) Filed: Dec. 28, 2021

Related U.S. Application Data
(63) Continuation of application No. PCT/JP2020/029324, filed on Jul. 30, 2020.

(30) Foreign Application Priority Data
Aug. 30, 2019 (JP) 2019-158466

(51) Int. Cl. H01L 21/67; H01L 21/673; C23C 16/46

(52) U.S. Cl. CPC H01L 21/67115; C23C 16/466; H01L 21/67303

(57) ABSTRACT

There is provided a technique that includes a reaction container in which an object to be processed, containing a semiconductor, is arranged; a heater configured to emit heat; and a radiation control body arranged between the reaction container and the heater, wherein the radiation control body is configured to radiate a radiant wave of a wavelength transmittable through the reaction container by selecting a wavelength of a radiation heat from the heater such that the radiant wave reaches the object to be processed in the reaction container.

### CROSS-REFERENCE TO RELATED APPLICATION

This application is a Bypass Continuation Application of PCT International Application No. PCT/JP2020/029324, filed on Jul. 30, 2020, the international application being based upon and claiming the benefit of priority from Japanese Patent Application No. 2019-158466, filed on Aug. 30, 2019, the entire contents of which are incorporated herein by reference.

### TECHNICAL FIELD

The present disclosure relates to a method of manufacturing a semiconductor device and an apparatus for manufacturing a semiconductor device.

### BACKGROUND

For example, in a process of manufacturing a semiconductor device, a vertical substrate processing apparatus (hereinafter, also referred to as a “vertical apparatus”) may be used as an apparatus for processing a semiconductor wafer (hereinafter, also simply referred to as a wafer), which is an object to be processed, including a semiconductor. The vertical apparatus may have a configuration in which in a state where a substrate holder (boat) for holding a plurality of wafers in multiple stages is accommodated in a quartz reaction container (hereinafter, also referred to as a “quartz reaction tube”), by radiating a radiant wave from a heating heater arranged on the outer peripheral side of the quartz reaction tube and causing the radiant wave transmitted through the quartz reaction tube to reach the wafers, the wafers are heated to a predetermined temperature for processing.

In the vertical apparatus having the above-described configuration, due to the fact that a wavelength of the radiant wave from the heating heater, a wavelength transmitted through the quartz reaction tube, and a wavelength absorbed by an object to be processed (wafer) are different from each other, processing for the object to be processed may not be performed efficiently and appropriately.

### SUMMARY

Some embodiments of the present disclosure provide a technique capable of efficiently and appropriately processing an object to be processed.

According to one or more embodiments of the present disclosure, there is provided a technique that includes a reaction container in which an object to be processed, containing a semiconductor, is arranged; a heater configured to emit heat; and a radiation control body arranged between the reaction container and the heater, wherein the radiation control body is configured to radiate a radiant wave of a wavelength transmittable through the reaction container by selecting a wavelength of a radiation heat from the heater such that the radiant wave reaches the object to the reaction container.

### BRIEF DESCRIPTION OF DRAWINGS

The accompanying drawings, which are incorporated in and constitute a part of the specification, illustrate embodiments of the present disclosure.

FIG. 1 is a side sectional view schematically showing a schematic configuration example of a semiconductor manufacturing apparatus according to a first embodiment of the present disclosure.

FIG. 2 is a side sectional view schematically showing a configuration example of a radiation control body in the semiconductor manufacturing apparatus according to the first embodiment of the present disclosure.

FIG. 3 is a conceptual diagram schematically showing an example of heat radiation control by a heating structure of the semiconductor manufacturing apparatus according to the first embodiment of the present disclosure.

FIGS. 4A and 4B are perspective views schematically showing an arrangement example of the radiation control body in the semiconductor manufacturing apparatus according to the first embodiment of the present disclosure.

FIG. 5 is a plane view schematically showing an arrangement example of the radiation control body in the semiconductor manufacturing apparatus according to the first embodiment of the present disclosure.

FIG. 6 is an explanatory diagram (first one) schematically showing another arrangement example of the radiation control body in the semiconductor manufacturing apparatus according to the first embodiment of the present disclosure.

FIG. 7 is an explanatory diagram (second one) schematically showing another arrangement example of the radiation control body in the semiconductor manufacturing apparatus according to the first embodiment of the present disclosure.

FIG. 8 is an explanatory diagram (third one) schematically showing another arrangement example of the radiation control body in the semiconductor manufacturing apparatus according to the first embodiment of the present disclosure.

FIG. 9 is an explanatory diagram (fourth one) schematically showing another arrangement example of the radiation control body in the semiconductor manufacturing apparatus according to the first embodiment of the present disclosure.

FIG. 10 is a side sectional view schematically showing a schematic configuration example of a semiconductor manufacturing apparatus according to a second embodiment of the present disclosure.

FIGS. 11A and 11B are explanatory diagrams schematically showing an arrangement example of a radiation control body in a semiconductor manufacturing apparatus according to another embodiment of the present disclosure.

FIG. 12 is an explanatory diagram schematically showing an arrangement example of a radiation control body in a semiconductor manufacturing apparatus according to still another embodiment of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of the present disclosure will be described with reference to the drawings.

A substrate processing apparatus given as an example in the following embodiments is used in a process of manufacturing a semiconductor device, and is configured as a vertical substrate processing apparatus that collectively processes a plurality of semiconductor substrates, which are objects to be processed, including a semiconductor.

An example of the semiconductor substrate (wafer), which is the object including a semiconductor, may include a semiconductor wafer, a semiconductor package, or the like in which a semiconductor integrated circuit device is built. In addition, when the term “wafer” is used in the present disclosure, it may mean a “wafer itself” or “a laminate (aggregate) of certain layers or films formed on the surface thereof)” (that is, a wafer including a certain layer, film, etc. formed on the surface thereof). Further, when the term “surface of a wafer” is used in the present disclosure, it may mean a “surface (exposed surface) of a wafer itself” or a “surface of a certain layer or film formed on the wafer, that is, the outermost surface of the wafer as a laminate.”

Further, a process performed by the substrate processing apparatus on the wafer may be any process performed by heating the wafer to a predetermined temperature, for example, an oxidation process, a diffusion process, a reflow or annealing process for carrier activation and planarization after ion doping, a film-forming process, etc. In particular, the present embodiment takes the film-forming process as an example. Further, an apparatus for manufacturing the semiconductor device may be referred to as a semiconductor device manufacturing apparatus which is a kind of substrate processing apparatus.

### First Embodiment

First, a first embodiment of the present disclosure will be specifically described.

### (1) Configuration of Reaction Tube

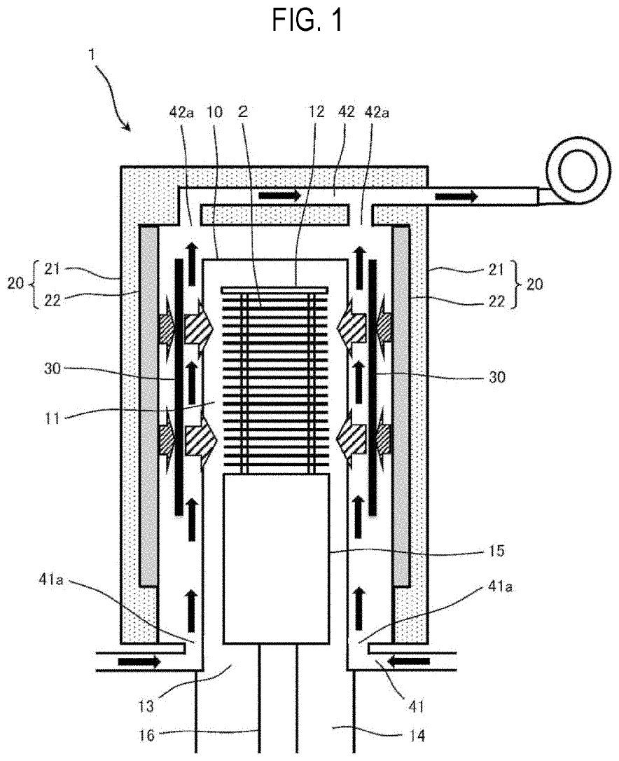

A semiconductor manufacturing apparatus 1 shown in FIG. 1 includes a process tube 10 as a vertical reaction tube. The process tube 10 is made of, for example, quartz (SiO₂), which is a heat resistant material, and is formed in a cylindrical shape with its upper end closed and its lower end opened. The process tube 10 may have a double-tube structure having an internal tube (inner tube) and an external tube (outer tube).

A process chamber 11 for processing wafers 2 is formed inside the process tube 10 (that is, in the inside of the cylindrical shape). The process chamber 11 is configured to accommodate the wafers 2 supported by a boat 12, which will be described later, in a state where the wafers 2 are arranged vertically in multiple stages. Further, a furnace opening 13 for loading/unloading the boat 12 is configured in a lower end opening of the process tube 10.

A lower chamber (load lock chamber) 14 constituting a load lock chamber for wafer transfer is arranged under the process tube 10. The lower chamber 14 is made of, for example, a metal material such as stainless steel (SUS) and is configured so as to form a closed space communicating with the process chamber 11 in the process tube 10 through the furnace opening 13.

In a space formed by the process tube 10 and the lower chamber 14, the boat 12 as a substrate support for supporting the wafers 2 is arranged so as to be movable in the vertical direction in the space. More specifically, the boat 12 is connected to a support rod 16 of an elevator (a boat elevator) via a heat insulating cap 15 arranged under the boat 12, and transitions between a state where the boat 12 is arranged in the process tube 10 (a wafer processable state) and a state where the boat 12 is arranged in the lower chamber 14 (a wafer transferable state) by the operation of the elevator. Further, in the state where the boat 12 is arranged in the process tube 10, the furnace opening 13 of the process tube 10 is sealed by a seal cap (not shown), whereby an airtight state in the process tube 10 is maintained. Further, the elevator for moving the boat 12 up and down may have a function as a rotator for rotating the boat 12.

The boat 12 that supports the wafers includes a pair of end plates and a plurality of holders (for example, three holders) vertically erected between the end plates. When the wafers 2 are put on the same stage of holding grooves engraved at equal intervals in the longitudinal direction of each holder, the boat 12 is configured to hold the wafers 2 with the wafers 2 arranged horizontally and with the centers of the wafers 2 aligned with each other. The boat 12 is made of, for example, a heat resistant material such as quartz or SiC. Further, since the boat 12 is supported via the heat insulating cap 15 arranged under the boat 12, the boat 12 is accommodated in the process tube 10 in a state where the boat 12 is separated by an appropriate distance from a position of the furnace opening 13 at which a lower end of the boat 12 is arranged. That is, the heat insulating cap 15 is designed to insulate the vicinity of the furnace opening 13, and has a function of suppressing heat conduction downward from the boat 12 holding the wafers 2 to assist with precise wafer temperature control.

A nozzle (not shown) extending from a lower region of the process chamber 11 to an upper region thereof is provided in the process tube 10 in which the boat 12 is accommodated. The nozzle is provided with a plurality of gas supply holes arranged along an extension direction thereof. As a result, a predetermined type of gas is supplied to the wafer 2 from the gas supply holes of the nozzle. The type of gas supplied from the nozzle may be preset according to the contents of processing in the process chamber 11. For example, in the case of performing a film-forming process, it is conceivable to supply a precursor gas, a reaction gas, an inert gas, etc. used for the film-forming process to the process chamber 11, as the predetermined type of gas.

Further, an exhaust pipe (not shown) for exhausting an atmospheric gas of the process chamber 11 is connected to the process tube 10. A pressure sensor, an auto pressure controller (APC) valve, a vacuum pump, and the like are connected to the exhaust pipe, whereby an internal pressure of the process chamber 11 can be adjusted.

### (2) Configuration of Heater

On the outside of the process tube 10, a heater 20 as a heater assembly (a heating mechanism or a heating system) is arranged at a position at which the heater 20 is concentric with the process tube 10 in order to heat the wafers 2 in the process tube 10.

The heater 20 includes a heat insulating case 21 arranged so as to cover the outer side of the heater 20. The heat insulating case 21 has a function of suppressing heat conduction from a heating heater 22, which will be described later, to the outside of the apparatus. To this end, the heat insulating case 21 is made of, for example, a metal material such as stainless steel (SUS) and is formed in a barrel shape, preferably a cylindrical shape, with its upper end closed and its lower end opened.

Further, the heater 20 includes with the heating heater 22, which is a heating element that generates heat, on the inner side of the heat insulating case. The heating heater 22 is arranged so that a heat generating surface thereof faces an outer peripheral surface of the process tube 10.

As the heating heater 22, it is conceivable to use, for example, a lamp heating heater of a heating type using infrared radiation by a halogen lamp, or a resistance heating heater of a heating type using Joule heat by electric resistance. However, the lamp heating heater is not practical because of its high cost and short life. Further, due to its fast rising/falling temperature, the lamp heating heater has a possibility of an increase of a wafer-to-wafer (WTW) or wafer-in-wafer (WIW) temperature deviation in a temperature range of, for example, 400 degrees C. or higher. On the other hand, the resistance heating heater has a small WTW temperature deviation and a small WIW temperature deviation, but has a low rising temperature rate in a low temperature range of, for example less than 400 degrees C. In particular, in the semiconductor manufacturing apparatus 1 of the present embodiment, when the resistance heating heater is used as the heating heater 22, due to the fact that a wavelength of a radiant wave radiated from the resistance heating heater, a wavelength transmitted through the process tube 10 made of quartz, and a wavelength absorbed by the wafers 2, which are the objects to be processed, in the process chamber 11 are different from each other, the radiant wave does not reach the wafers 2 efficiently, and therefore, the resistance heating heater may take longer time to raise the temperature than the case of the lamp heating heater.

Based on the above, the semiconductor manufacturing apparatus 1 of the present embodiment uses a resistance heating heater as the heating heater 22 to thereby achieve the low cost and long life of the heating heater 22 and further achieve both the improvement of temperature rise performance in a low temperature range (for example, less than 400 degrees C.) and the maintenance of stable performance (the elimination of deviation) in a medium temperature range (for example, 400 degrees C. or higher, and lower than 650 degrees C.) by arranging a radiation control body 30 between the process tube 10 and the heater 20 and controlling a radiation intensity in a wavelength-selective manner by the radiation control body 30, as will be described in detail later.

### (3) Configuration of Radiation Control Body

The radiation control body 30 is arranged between the process tube 10, which is a reaction tube (hereinafter, also referred to as a “quartz tube”) made of quartz, and the heating heater 22 in the heater 20.

The radiation control body 30 is used to control the radiation intensity of a radiant wave radiated toward the process tube 10 in a wavelength-selective manner. More specifically, the radiation control body 30 is configured to radiate a radiant wave of a wavelength band, which is different from that of the radiation heat from the heating heater 22, toward the process tube 10 according to the heating from the heating heater 22 in the heater 20. That is, the heat generated from the heating heater 22 is wavelength-converted by the radiation control body 30 and is radiated toward the process tube 10. The term “wavelength conversion” as used herein means a concept that broadly includes radiating heat in a wavelength band different from that when heat is received. Therefore, for example, not only a case where a portion of a wavelength band of radiant wave at which heat is received is extracted and radiated but also a case where a completely new wavelength band of radiant wave is generated and radiated according to the heat reception corresponds to the “wavelength conversion” as used herein.

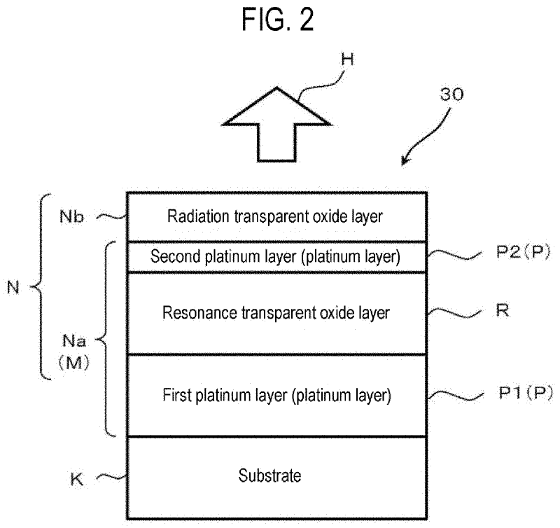

As a specific example of the radiation control body 30 that performs such wavelength conversion, one configured as follows can be mentioned. FIG. 2 is a side sectional view schematically showing a configuration example of a radiation control body in a semiconductor manufacturing apparatus according to a first embodiment.

The radiation control body 30 shown in FIG. 2 is formed as a plate-like body arranged between the heating heater 22 and the process tube 10, and is configured by laminating a substrate K located on a side of the heating heater 22 and a heat radiation layer N located on the process tube 10 side.

The substrate K is configured to be in a high temperature state (for example, 800 degrees C.) by the heat from the heating heater 22, thereby heating the heat radiation layer N which is a laminating partner. The substrate K may be any one as long as it can be in a high temperature state, and can be formed using, for example, various heat resistant materials such as quartz (SiO2), sapphire (Al₂O₃), stainless steel (SUS), Kanthal, nichrome, aluminum, and silicon.

When the heat radiation layer N is heated by the substrate K in the high temperature state, the heat radiation layer N is configured to radiate a radiant wave having a wavelength, which will be described in detail later, to the process tube 10 side by the heating. Therefore, the heat radiation layer N is configured by laminating a radiation controller Na and a radiation transparent oxide layer Nb, which is made of transparent oxide such as alumina (aluminum oxide, Al₂O₃), sequentially from substrate K side. Of these, the radiation controller Na includes a lamination part M having a so-called MIM (Metal Insulator Metal) structure in which a resonance transparent oxide layer R made of transparent oxide such as alumina is located between platinum layers P as a pair of metal layers arranged along the laminating direction of the substrate K and the heat radiation layer N.

In other words, the radiation controller Na of the heat radiation layer N in the radiation control body 30 has the lamination part M including the platinum layers P, which are metal layers, and the resonance transparent oxide layer R which is an oxide layer. The lamination part M has the MIM structure in which the resonance transparent oxide layer R is located between a pair of platinum layers P. Hereinafter, of the pair of platinum layers P, a platinum layer P adjacent to the substrate K is referred to as a first platinum layer P1, and a platinum layer P adjacent to the radiation transparent oxide layer Nb is referred to as a second platinum layer P2. That is, the radiation control body 30 is configured to form the first platinum layer P1, the resonance transparent oxide layer R, the second platinum layer P2, and the radiation oxide layer Nb sequentially from the substrate K side (that is, the heating heater 22 side).

Further, in the lamination part M of the MIM structure (hereinafter, also referred to as a “MIM lamination part”), the resonance transparent oxide layer R is set to have a thickness having a wavelength (specifically, for example, 4 μm or less) transmitted through the process tube (quartz tube) 10 as a resonance wavelength.

In the radiation control body 30 having the above configuration, when the heat radiation layer N is heated by the substrate K in the high temperature state, the platinum layers P (the first platinum layer P1 and the second platinum layer P2) of the radiation controller Na radiate a radiant wave. At this time, the radiation rate (emissivity) of the radiant wave tends to gradually increase toward a short wavelength in a wavelength range of 4 μm or less, and maintains a low value in a wavelength range of more than 4 μm. Further, since the thickness of the resonance transparent oxide layer R of the MIM lamination part M is set to a thickness having the wavelength of 4 μm or less, which is the wavelength transmitted through the quartz tube 10, as the resonance wavelength, the wavelength of 4 μm or less (that is, a wavelength in a narrow band below mid-infrared light) is amplified by the action of resonance. Therefore, an amplified radiant wave H having the wavelength of 4 μm or less is emitted to the outside from the radiation transparent oxide layer Nb.

In this way, the resonance transparent oxide layer R is configured to amplify the radiant wave while repeatedly reflecting the radiant wave between the platinum layers P (the first platinum layer P1 and the second platinum layer P2). Therefore, when the thickness of the resonance transparent oxide layer R is set so that the wavelength of 4 μm or less (that is, the wavelength transmitted through the quartz tube 10) becomes the resonance wavelength, the radiant wave having the wavelength of 4 μm or less is amplified, and then, the amplified radiant wave having the wavelength of 4 μm or less is emitted to the outside. On the other hand, a radiant wave having a wavelength of more than 4 μm is emitted to the outside from the radiation transparent oxide layer Nb in a state where the radiant wave is less likely to be amplified by the action of resonance. As a result, the radiant wave H from the radiation transparent oxide layer Nb has a large radiation rate (emissivity) in a narrow band wavelength of 4 μm or less (narrow band wavelength below mid-infrared light), and has a small radiation rate (emissivity) in a wavelength of more than 4 μm (wavelength of far-infrared light).

That is, the radiation control body 30 shown in FIG. 2 is adapted to radiate mainly the radiant wave having the wavelength of 4 μm or less amplified by the MIM lamination part M, as the radiant wave having the wavelength transmitted through the process tube (quartz tube) 10, to the outside from the radiation transparent oxide layer Nb.

At this time, in the MIM lamination part M, the first platinum layer P1 can be configured to shield the radiant wave from the substrate K side (that is, the heating heater 22 side). In this way, when the first platinum layer P1 shields the radiant wave to suppress transmission through the inside of the radiation control body 30 (particularly, the resonance transparent oxide layer R in the MIM lamination part M), the influence on the radiant wave emitted from the radiation control body 30 is suppressed.

Further, in the MIM lamination part M, the second platinum layer P2 can be configured to transmit a portion of the radiant wave from the substrate K side (that is, the heating heater 22 side). More specifically, the second platinum layer P2 can be configured to transmit the radiant waves having the narrow band wavelength of 4 μm or less, which is the wavelength transmitted through the process tube (quartz tube) 10. In this way, when the second platinum layer P2 transmits a portion of the radiant wave, as a result, the radiant wave having the wavelength of 4 μm or less (that is, the wavelength transmitted through the quartz tube 10) amplified by the MIM lamination part M is emitted to the outside from the radiation control body 30.

Further, the radiation transparent oxide layer Nb has a lower refractive index than the second platinum layer P2, which is a metal layer, and has a higher refractive index than air. When such a radiation transparent oxide layer Nb is arranged adjacent to the second platinum layer P2, the reflectance in the second platinum layer P2 is reduced, and as a result, the radiant wave is well emitted to the outside from the radiation control body 30.

Although the case where the radiation controller Na includes one MIM lamination part M as the heat radiation layer N is exemplified here, the radiation controller Na may include a plurality of MIM lamination parts M. Including a plurality of MIM lamination parts M means a configuration in which three or more platinum layers P arranged along the laminating direction of the heat radiation layer N and the substrate K are provided and the resonance transparent oxide layer R is located between adjacent platinum layers P.

Further, here, as a specific example of the radiation control body 30, one having the configuration shown in FIG. 2 (that is, one provided with the MIM lamination part M) is illustrated, but the radiation control body 30 may be configured by using a wavelength control technique other than that by the MIM lamination part M as long as it has a function of wavelength-converting the heat from the heating heater 22 and radiating it toward the process tube 10. An example of one using another wavelength control technique may include a radiation control body configured by a quartz plate having characteristics as an optical filter. The radiation control body (quartz plate) having such a configuration transmits 90% or more of wavelengths of about 4 μm or less, and conversely absorbs most of wavelengths longer than that. Therefore, of the radiant energy from the heating heater 22, the radiant wave having the wavelength of 4 μm or less is radiated to the process tube 10 side, as the radiant wave having the wavelength transmitted through the process tube 10. Further, the radiation control body 30 may be configured by using other known techniques (wavelength control techniques).

While the radiation control body 30 having the above configuration is arranged between the process tube 10 and the heating heater 22 and is used, in the semiconductor manufacturing apparatus 1 shown in FIG. 1, the radiation control body 30 is arranged apart from the heat generating surface (heat radiating surface) of the heating heater 22 in the heater 20. In that case, when the radiation control body 30 is arranged between the process tube 10 and the heating heater 22 so that a distance from the heating heater 22 is closer than a distance from the process tube 10, the radiation control body 30 can be efficiently heated, and it is also preferable for cooling the process tube 10 by a cooler (cooling mechanism) to be described later.

The radiation control body 30 may be arranged between the process tube 10 and the heating heater 22 by using a holder (not shown in FIG. 1) that supports the radiation control body 30. As the holder, one configured to suspend and support the radiation control body 30 from the upper side can be used. However, the present disclosure is not limited thereto, but the radiation control body 30 may be supported by another configuration, for example, one that supports the lower end of the radiation control body 30 on the lower side.

A specific form of the arrangement of the radiation control body 30 and the support by the holder will be described in detail later.

### (4) Configuration of Cooler (Cooling Mechanism)

The semiconductor manufacturing apparatus 1 shown in FIG. 1 is provided with a cooler (cooling mechanism) in addition to the above-described process tube 10, heater 20, and radiation control body 30.

The cooler is mainly used to cool the process tube 10, and includes at least an introduction part 41 that introduces a cooling gas between the process tube 10 and the heating heater 22 in the heater 20, and an exhauster 42 for exhausting the introduced cooling gas. As the cooling gas, a known gas (for example, an inert gas such as a N₂ gas) may be used. Further, components (a gas supply source, etc.) of the introduction part 41 and components (an exhaust pump, etc.) of the exhauster 42 may also be those using known techniques, and detailed explanation thereof will be omitted here.

Further, in the cooler, a gas introduction port 41a of the introduction part 41 and a gas exhaust port 42a of the exhauster are arranged so that the cooling gas flows in the vicinity of an outer peripheral surface of the process tube 10 along the process tube 10. That is, the cooling gas mainly flows between the process tube 10 and the radiation control body 30 along the process tube 10.

When such a cooler is provided, it is possible to suppress the process tube 10 from being in a high temperature state by flowing the cooling gas. In particular, when the cooling gas is allowed to flow in the vicinity of the outer peripheral surface of the process tube 10, the flow velocity of the cooling gas in the vicinity of the outer peripheral surface is made the fastest and thus, the cooling gas in the low temperature (normal temperature) state comes into contact with the process tube 10, which can improve the cooling efficiency.

### (5) Procedure of Basic Processing Operation

Next, an outline of the basic processing operation in the semiconductor manufacturing apparatus 1 having the above-described configuration will be described. Here, as a process of manufacturing a semiconductor device, a processing operation in a case of performing a film-forming process on a wafer 2 will be given as an example.

As shown in FIG. 1, when the boat 12 is charged with a predetermined number of wafers 2, the boat 12 holding the wafers 2 is loaded into the process chamber 11 (boat loading) by the operation of the boat elevator. Then, when the operation of the boat elevator reaches the upper limit, the furnace opening 13 of the process tube 10 is sealed, so that the airtight state of the process chamber 11 is maintained in a state where the wafers 2 are accommodated.

After that, the interior of the process chamber 11 is exhausted by an exhaust pipe (not shown) and is adjusted to a predetermined pressure. Further, the interior of the process chamber 11 is heated to a target temperature by utilizing the heat generated by the heating heater 22 in the heater 20 (see a hatched arrow in FIG. 1). A specific form of the heating at this time will be described in detail later. Further, the boat 12 is rotated by the boat elevator (rotation mechanism). Further, when the interior of the process chamber 11 is heated, the process tube 10 can be cooled by the cooling gas (see a black arrow in FIG. 1).

When the internal pressure and temperature of the process chamber 11 and the rotation of the boat 12 become stable as a whole, a predetermined type of gas (for example, a precursor gas) is supplied into the process chamber 11 from a nozzle (not shown). The gas supplied into the process chamber 11 flows so as to touch the wafers 2 accommodated in the process chamber 11 and then is exhausted by the exhaust pipe (not shown). At this time, in the process chamber 11, for example, a predetermined film is formed on the wafers 2 by a thermal CVD reaction caused by contact of the precursor gas with the wafers 2 heated to a predetermined processing temperature.

When a film having a desired film thickness is formed on the wafers 2 with the lapse of predetermined processing time, the supply of the precursor gas and the like is stopped, while an inert gas (purge gas) such as a N2 gas is supplied into the process chamber 11 to substitute the internal gas atmosphere of the process chamber 11. Further, the heating by the heating heater 22 is stopped to lower the temperature of the process chamber 11. Then, when the temperature of the process chamber 11 drops to a predetermined temperature, the boat 12 holding the wafers 2 is unloaded from the process chamber 11 (boat unloading) by the operation of the boat elevator.

After that, by repeating the above-described film-forming process, a film-forming step for the wafers 2 is carried out.

In the film-forming process described above, the operations of various parts constituting the semiconductor manufacturing apparatus 1 is controlled by a controller (not shown) included in the semiconductor manufacturing apparatus 1. The controller functions as a control part (control means) of the semiconductor manufacturing apparatus 1, and includes hardware resources as a computer apparatus. Then, the hardware resources execute a program (for example, a control program) or a recipe (for example, a process recipe) which is predetermined software, so that the hardware resources and the predetermined software cooperate with each other to control the above-described processing operation.

The controller as described above may be configured as a dedicated computer or a general-purpose computer. For example, the controller according to the present embodiment can be configured, for example by preparing an external storage device (for example, a magnetic tape, a magnetic disk such as a flexible disk or a hard disk, an optical disc such as a CD or DVD, a magneto-optic disc such as a MO, a semiconductor memory such as a USB memory or a memory card, etc.) in which the above-mentioned program is stored, and installing the program on the general-purpose computer using the external storage device. Further, a means for supplying the program to the computer is not limited to a case of supplying the program via the external storage device. For example, a communication means such as the Internet or a dedicated line may be used, or information may be received from a host device via a receiving part and the program may be supplied without going through the external storage device.

A storage device in the controller and the external storage device that can be connected to the controller are configured as a non-transitory computer-readable recording medium. Hereinafter, these are collectively referred to simply as a recording medium. In addition, when the term “recording medium” is used in the present disclosure, it may include a storage device alone, an external storage device alone, or both of them.

### (6) Specific Example of Heat Radiation Control

Subsequently, among the series of processing operations described above, a heating process of heating the interior of the process chamber 11 by utilizing the heat generated by the heating heater 22 will be described in more detail.

In the heating process, the radiant wave reaches the wafers 2 via the process tube 10 to raise the temperature of the wafers 2. However, in the heating process, it may be preferable to rapidly raise the temperature of the wafers 2 from room temperature (normal temperature) to a set temperature of, for example, 300 to 400 degrees C. and to precisely control the temperature of the wafers 2. To this end, it is possible to irradiate the wafers 2 with radiation of a wavelength band absorbed by the wafers 2 with sufficient intensity for rapid temperature rise without raising the temperature of the process tube 10 too high (for example, 400 degrees C. or higher). If the temperature of the process tube 10 rises too high (for example, when it reaches 500 degrees C. or higher), even if the heat generation from the heating heater 22 is stopped after the wafers 2 reaches the set temperature of, for example, 300 to 400 degrees C., there is a possibility that an overshoot phenomenon may occur in which the temperature of the wafers 2 continues to rise due to heat transfer from the process tube 10 which has been in the high temperature state. When such a phenomenon occurs, the time for precisely controlling the wafers 2 to reach the set temperature becomes extremely long, and as a result, the productivity of the substrate processing for the wafer 2 decreases.

Further, as already described, it is preferable to use the resistance heating heater instead of the lamp heating heater as the heating heater 22 from the viewpoint of low cost and long life of the heating heater 22. However, when the resistance heating heater is simply used as the heating heater 22, the radiant wave does not reach the wafers 2 efficiently, and therefore, there is a possibility that the temperature rise time will be longer than in the case of the lamp heating heater.

Based on the above, the semiconductor manufacturing apparatus 1 of the present embodiment has a heating structure configured so that the radiation control body 30 is arranged between the process tube 10 and the heating heater 22 and the heat radiation control is performed by the radiation control body 30. Such a heating structure includes at least the heating heater 22 that emits heat, and the radiation control body 30 that performs the heat radiation control, and is configured so that the radiation control body 30 radiates the radiant wave (specifically, the radiant wave having the wavelength of 4 μm or less, which is the wavelength transmitted through the process tube 10) of a wavelength band different from the radiation heat from the heating heater 22, to the process tube 10. Hereinafter, a part constituting such a heating structure may be referred to as a “heat radiation device.”

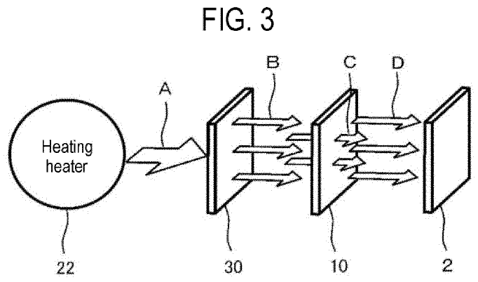

Here, the heat radiation control in this heating structure will be described in more detail with a case where a wafer 2, which is an object to be processed, is a silicon wafer, as a specific example. FIG. 3 is a conceptual diagram schematically showing an example of the heat radiation control by a heating structure of the semiconductor manufacturing apparatus according to the first embodiment.

In the heating structure shown in FIG. 3, first, the heating heater 22 generates heat in the heating process. At this time, if the heating heater 22 is a resistance heating heater, for example, considering a wavelength band radiated from a gray body having a heating element temperature of about 1,100K at the time of temperature rise, the resistance heating heater emits a radiant wave of a wavelength band of 0.4 to 100 μm and 100 μm or more (that is, a wavelength band in a range from near-infrared, mid-infrared, to far-infrared) (see an arrow A in the figure). The radiation control body 30 is heated by this radiant wave.

When the radiation control body 30 is heated, the radiation control body 30 radiates a new radiant wave of a wavelength band, which is different from the radiation heat from the heating heater 22 by a wavelength-selective radiant intensity control, toward the process tube 10 side (see an arrow B in the figure). Specifically, the radiation control body 30 radiates, for example, a radiant wave of a narrow band wavelength of mainly 4 μm or less (a narrow band wavelength below mid-infrared light), preferably a radiant wave of a narrow band wavelength of mainly 1 μm or less (a narrow band wavelength including a near-infrared region), toward the process tube 10 side.

The radiant wave from the radiation control body 30 substantially passes through the process tube 10 if it has a wavelength of mainly 4 μm or less (including a wavelength of 1 μm or less). In other words, if the radiant wave of a wavelength larger than 4 μm (a wavelength of far infrared light) is suppressed, absorption in the process tube 10 is less likely to occur. As a result, even when the radiant wave from the radiation control body 30 arrives, it is difficult for the process tube 10 to be heated by the radiant wave, and thus, the temperature of the process tube 10 is suppressed from rising more than necessary (for example, 500 degrees or higher), and the process tube 10 transmits the radiant wave that arrived as it is (see an arrow C in the figure). When the temperature rise of the process tube 10 can be suppressed in this way, reaction products and the like adhering to an inner wall of the process tube 10 can be reduced, and as a result, it is possible to extend a cleaning cycle and a replacement cycle of the process tube 10.

At this time, when the cooler allows the cooling gas to flow, it is even more effective in suppressing the temperature rise of the process tube 10.

The radiant wave (for example, the radiant wave of a narrow band wavelength of 1 μm or less, which is mainly in the near-infrared region) transmitted through the process tube 10 reaches the wafer 2 and is absorbed by the wafer 2 (see an arrow D in the figure). That is, the radiation control body 30 radiates the radiant wave of the wavelength transmitted through the process tube 10 according to the heating from the heating heater 22, and performs the radiation control to cause the radiant wave to reach the wafer 2 in the process tube 10.

As a result, the wafer 2 is heated to the target temperature and is adjusted to maintain that temperature. At this time, when the radiant wave having a sufficient intensity for the rapid temperature rise reaches the wafer 2, the temperature of the wafer 2 can rapidly rise. Moreover, even in that case, since the temperature rise of the process tube 10 itself can be suppressed, there is no adverse effect due to the high temperature of the process tube 10. Therefore, even when the heating heater 22 is the resistance heating heater, it is possible to efficiently cause the radiant wave to reach the wafer 2, thereby realizing the rapid temperature rise of the wafer 2. Moreover, it is easily possible to realize precise control so that the wafer 2 reaches a set temperature after the temperature rise of the wafer 2.

As described above, in the heating structure using the radiation control body 30, without raising the temperature of the process tube 10 more than necessary (for example, 400 to 500 degrees C. or higher), it is possible to allow the radiant wave of the wavelength band (for example, 4 μm or less, specifically 1 μm or less) absorbed by the wafer 2 to reach the wafer 2 with the sufficient intensity for rapid temperature rise. Therefore, according to such a heating structure, by controlling the radiation intensity in a wavelength-selective manner by the radiation control body 30, it is possible to achieve the low cost and long life of the heating heater 22 and further achieve both the improvement of temperature rise performance in a low temperature range (for example, less than 400 degrees C.) and the maintenance of stable performance (the elimination of deviation) in a medium temperature range (for example, 400 degrees C. or higher, and lower than 650 degrees C.).

The heat radiation device constituting such a heating structure includes at least the heating heater 22 of the heater 20, and the radiation control body 30. That is, the heat radiation device referred to here includes at least the heating heater 22 that emits heat to the process tube 10, and the radiation control body 30 arranged between the process tube 10 and the heating heater 22.

### (7) Arrangement Example of Radiation Control Body

Next, the arrangement of the radiation control body 30 for constructing the above-described heating structure will be described in more detail with specific examples.

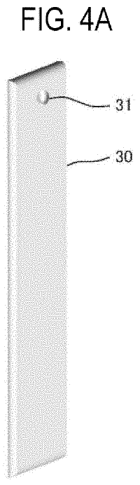

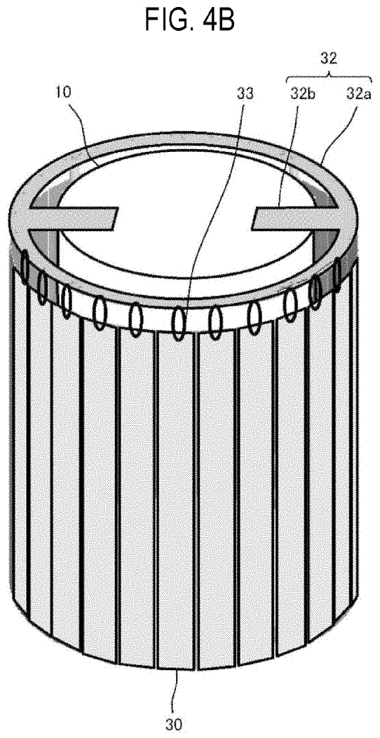

FIGS. 4A and 4B are perspective views schematically showing an example of arrangement of the radiation control body in the semiconductor manufacturing apparatus according to the first embodiment.

As shown in FIG. 4A, as the radiation control body 30, for example, a strip-shaped plate is used. Dimensions such as the length, width, and thickness of the plate-like body may be appropriately set according to the size of the process tube 10, the distance between the process tube 10 and the heating heater 22, and the like. It is assumed that the radiation control body 30 is provided with a locking hole 31 for suspending and supporting the radiation control body 30.

For example, when the radiation control body 30 is configured by laminating the substrate K and the heat radiation layer N (see FIG. 2), the radiation control body 30 is arranged between the process tube 10 and the heating heater 22 in a state where the substrate K is located on the heating heater 22 side and the heat radiation layer N is located on the process tube 10 side. At this time, when the radiation control body 30 is arranged so that the distance from the heating heater 22 is closer than the distance from the process tube 10, the radiation control body 30 can be efficiently heated, and it is also preferable for cooling the process tube 10 by the cooler.

Further, as shown in FIG. 4B, as the radiation control body 30 is suspended and supported by a holder 32, the radiation control body 30 is arranged between the process tube 10 and the heating heater 22.

The holder 32 has an annular portion 32a having a shape corresponding to the process tube 10. Here, the “corresponding shape” refers to a similar shape corresponding to the planar shape of the process tube 10. For example, if the process tube 10 has a cylindrical shape, the annular portion 32a becomes an annular shape concentric with the process tube 10. Further, the holder 32 has a plurality of mounting piece portions 32b (that is, at least two mounting piece portions 32b) mounted on the ceiling portion of the process tube 10 in addition to the annular portion 32a. Further, a plurality of connectors 33 are attached to the holder 32 at predetermined intervals in the circumferential direction of the annular portion 32a. The locking hole 31 of the radiation control body 30 is locked to each of the connectors 33. The holder 32 and the connector 33 can be made of, for example, a metal material having excellent heat resistance (for example, SUS). With such a configuration, the holder 32 is attached to the ceiling portion of the process tube 10, and suspends and supports a plurality of radiation control bodies 30 (for example, 27 radiation control bodies 30) so as to surround the circumference of the process tube 10.

According to the suspension/support structure as described above, the radiation control body 30 can be arranged with a very simple configuration. Therefore, for example, it is possible to easily cope with a case where the radiation control body 30 is additionally arranged in a wafer heating structure in the existing device. Further, if the connectors 33 are configured so that the radiation control body 30 can be attached and detached, it is possible to easily cope with a case where the radiation control body 30 is replaced as needed.

Further, according to the suspension/support structure, it is easily feasible to arrange the radiation control body 30 at an appropriate position. Specifically, it is easily feasible to arrange the radiation control body 30 at a position close to the heating heater 22 but not in contact with the heating heater 22 so that the radiation control body 30 can be efficiently heated.

Further, according to the suspension/support structure, by appropriately setting the width dimension of the radiation control body 30 and the arrangement interval of the radiation control bodies 30 (the attachment interval of the connector 33), it is possible to arrange the radiation control body 30 so as to surround the substantial entire side surface of the process tube 10. Specifically, for example, it is feasible to arrange a plurality of radiation control bodies 30 so as to cover 95% or more of the side surface of the process tube 10. When the radiation control bodies 30 are arranged so as to cover 95% or more of the side surface of the process tube 10, the radiant wave from the heating heater 22 can be suppressed from directly reaching the process tube 10, which is very preferable for efficient heating process.

Moreover, according to the suspension/support structure, even when the radiation control body 30 is the strip-shaped plate, the radiation control body 30 can surround the process tube 10. That is, as the radiation control body 30, the strip-shaped plate can be used. Therefore, it is easily feasible to appropriately adjust the configuration of the radiation control body 30 (for example, the thickness of the resonance transparent oxide layer R in the MIM lamination part M), and as a result, it is possible to optimize the heat radiation control.

In the case of the suspension/support structure, as the plate-shaped body length of the radiation control body 30 becomes longer (that is, as the tube length of the process tube 10 becomes longer), shaking at the lower end side of the suspended and supported radiation control body 30 is more likely to be a problem. Therefore, a connecting jig (not shown) for suppressing the shaking may be attached to the lower side of each radiation control body 30. As the connecting jig, for example, a jig configured to connect adjacent radiation control bodies 30 can be used.

By the way, such a suspension/support structure is used in a high temperature environment at the time of heat radiation control. Therefore, it is conceivable that thermal expansion occurs in the radiation control body 30 and the holder 32. Based on this, it is assumed that the holder 32 supports the radiation control body 30 in the following manner.

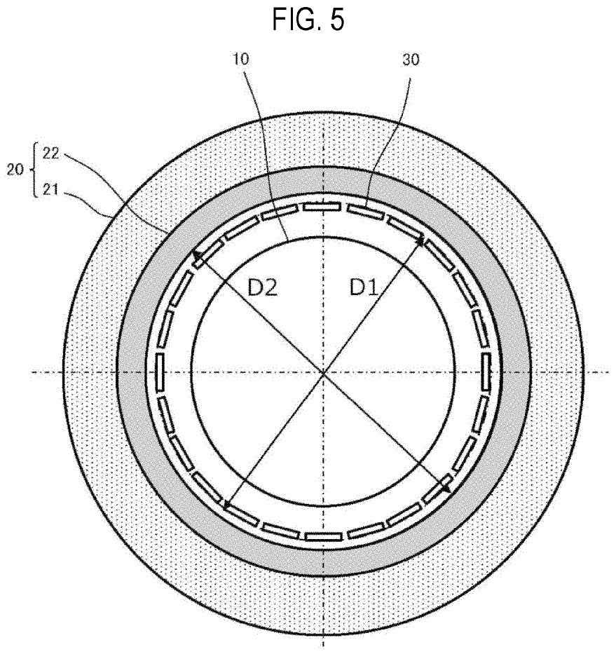

FIG. 5 is a plane view schematically showing an arrangement example of the radiation control body in the semiconductor manufacturing apparatus according to the first embodiment. As shown in FIG. 5, the holder 32 is set with a clearance of the radiation control body 30 to the heating heater 22 so that the suspended and supported radiation control body 30 does not interfere with the heating heater 22 even if thermal expansion occurs due to heating from the heating heater 22. More specifically, when in a high temperature state (for example, about 700 degrees C.) during the heat radiation control, even if the outer peripheral diameter (D1) of each radiation control body 30 arranged so as to surround the process tube 10 is increased due to thermal expansion, the mounting position of each connector 33 in the holder 32 is set so that the outer peripheral diameter (D1) of the radiation control body 30 does not reach the inner peripheral diameter (D2) of the heating heater 22.

According to the suspension/support structure as described above, even if the thermal expansion occurs due to the heating from the heating heater 22, interference between the radiation control body 30 and the heating heater 22 does not occur. Therefore, it is possible to prevent a situation in which the heat radiation control is hindered.

Further, since the outer peripheral diameter (D1) is increased between each of the radiation control bodies 30 being suspended and supported, interference between the radiation control bodies 30 does not occur due to the thermal expansion.

### (8) Another Arrangement Example of Radiation Control Body

The arrangement of the radiation control body 30 is not limited to the above-described form, and may be another form.

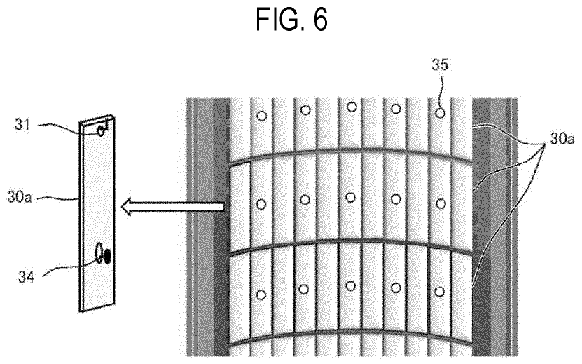

FIG. 6 is an explanatory diagram (first one 1) schematically showing another arrangement example of the radiation control body in the semiconductor manufacturing apparatus according to the first embodiment.

In the arrangement example of the form shown in FIG. 6, a longitudinal length of a radiation control body 30a is shorter than a tube length of the reaction container. A plurality of holders (not shown) are arranged in a plurality of stages along a pipe length direction of the process tube 10, and the holder in each stage suspends and supports the radiation control body 30a by using a locking hole 31. With such a support structure, a plurality of radiation control bodies 30a are arranged between the process tube 10 and the heating heater 22 so as to surround the circumference of the process tube 10, and are arranged in a tube length direction of the process tube 10. That is, the plurality of radiation control bodies 30a are arranged side by side in the form of a so-called matrix.

Each radiation control body 30a may be configured so that shaking is suppressed by a fixing pin 34 as a connecting jig. Further, some or all of the radiation control bodies 30a may be provided with a quenching hole 35 through which the cooling gas by the cooler passes in order to efficiently cool the process tube 10.

As described above, when the plurality of radiation control bodies 30a are arranged, each radiation control body 30a may be configured so that wavelength characteristics of the radiant wave radiated to the process tube 10 differ depending on the arrangement location.

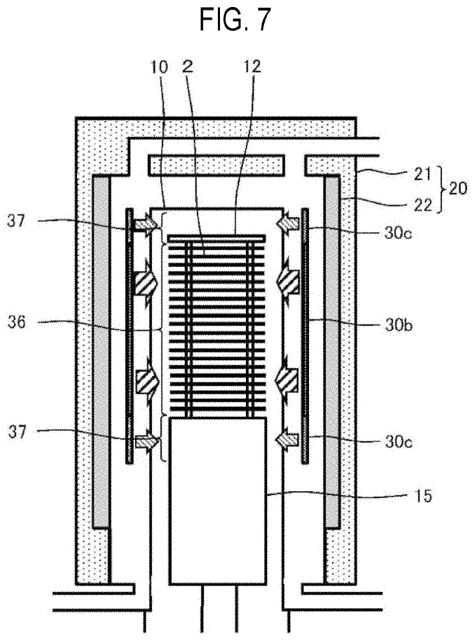

For example, when the plurality of radiation control bodies 30a are arranged side by side in the tube length direction of the process tube 10, it is conceivable to make the wavelength characteristics in each radiation control body 30a different as shown in FIG. 7. FIG. 7 is an explanatory diagram (second one) schematically showing another arrangement example of the radiation control body in the semiconductor manufacturing apparatus according to the first embodiment.

As shown in FIG. 7, a region (hereinafter, referred to as an “arrangement region”) 36 in which a wafer 2, which is an object to be processed, is arranged in a state of being supported by the boat 12 and other regions (hereinafter, referred to as a “non-arrangement region”) 37 are formed as different regions in the process tube 10.

Accordingly, for the plurality of radiation control bodies 30a, a radiation control body 30b suspended and supported by a stage corresponding to the arrangement region 36 and a radiation control body 30c suspended and supported by a stage corresponding to the non-arrangement region 37 have different wavelength characteristics of the radiant wave radiated to the process tube 10. Specifically, as the radiation control body 30b in the arrangement region 36, one having the wavelength characteristic of radiating a wavelength for efficiently heating the wafers 2, for example, a wavelength of mainly 4 μm or less, more specifically a wavelength of mainly 1 μm or less, is used. Further, as the radiation control body 30c in the non-arrangement region 37, one having the wavelength characteristic of radiating a wavelength for efficiently heating quartz of which the process tube 10 is made, for example, a wavelength of mainly 3 μm or more, more specifically a wavelength of mainly more than 4 μm, is used.

According to the arrangement example of such a configuration, the wafers 2 in the arrangement region 36 can be efficiently heated, and a ceiling plate and the heat insulating cap 15 of the process tube 10 in the non-arrangement region 37 located above and below the arrangement region 36 can be efficiently heated at the same time as the wafers 2. Therefore, even when the temperature of the wafers 2 rises faster due to efficient heating, the ceiling plate and the heat insulating cap 15 of the process tube 10 can act as a heat source, thereby preventing WTW and WIW temperature deviations from occurring in a temperature range of, for example, 400 degrees C. or higher. Needless to say, the present embodiment also includes a configuration in which the radiation control body 30 is not provided at a height position corresponding to a heat insulating plate region below a substrate arrangement region. According to this configuration, rather, since a quartz barrel and a quartz heat insulating plate are heating targets in the heat insulating plate region below the heater, it is preferable that the radiation control body 30 is not provided. This is because due to the absence of the radiation control body 30, the radiant wave including a wavelength absorbed by a quartz member is radiated, thereby further improving the heating efficiency of the heat insulating plate region.

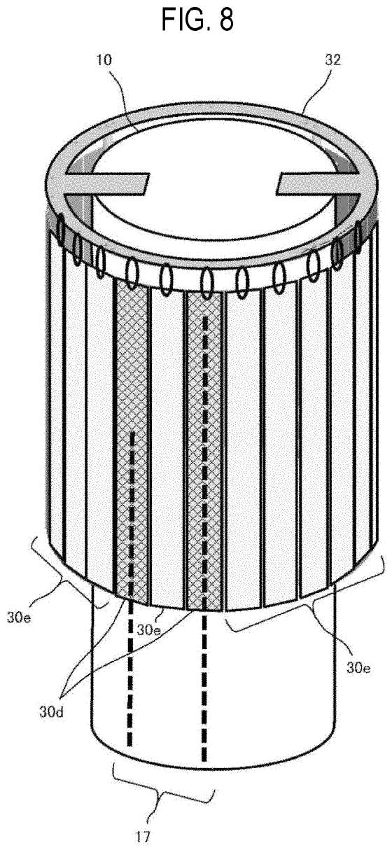

Further, for example, when a plurality of radiation control bodies 30 are arranged so as to surround the circumference of the process tube 10, it is conceivable to make wavelength characteristics of radiation control bodies 30d and 30e different, as shown in FIG. 8. FIG. 8 is an explanatory diagram (third one) schematically showing another arrangement example of the radiation control body in the semiconductor manufacturing apparatus according to the first embodiment.

As shown in FIG. 8, a nozzle 17 serving as a gas supply path is formed in the process tube 10, and a predetermined type of gas is supplied into the process chamber 11 through the nozzle 17.

Accordingly, for the plurality of radiation control bodies 30, a radiation control body 30d arranged at a location corresponding to the nozzle 17 and a radiation control body 30e arranged at other locations have different wavelength characteristics of the radiant wave radiated to the process tube 10. Specifically, as the radiation control body 30d that radiates the radiant wave to the location where the nozzle 17 is arranged, one having the wavelength characteristic of radiating a wavelength for efficiently heating quartz of which the process tube 10 is made, for example, a wavelength of mainly 3 μm or more, more specifically a wavelength of mainly more than 4 μm, is used. Further, as the radiation control body 30e arranged in other locations, one having the wavelength characteristic of radiating a wavelength for efficiently heating the wafers 2, for example, a wavelength of mainly 4 μtm or less, more specifically a wavelength of mainly 1 μm or less, is used.

According to the arrangement example of such a configuration, since a portion of the process tube 10 near a nozzle arrangement location is heated, the heat can be used to preheat a gas flowing through the nozzle 17. Therefore, it is feasible to improve the efficiency and appropriateness of the processing for the wafers 2 using the gas.

In the example of FIG. 8, a form in which the radiation control bodies 30d and 30e are arranged in one stage along the tube length direction of the process tube 10 (that is, a form in which the radiation control bodies 30d and 30e are not divided in the tube length direction of the process tube 10) is shown, but the present disclosure is not limited thereto. For example, even in the case where a plurality of radiation control bodies 30a are arranged side by side in a tube length direction of the process tube 10 as in the form shown in FIG. 6, the wavelength characteristics of the radiant wave in the vicinity of a nozzle arrangement location and in other locations may be different.

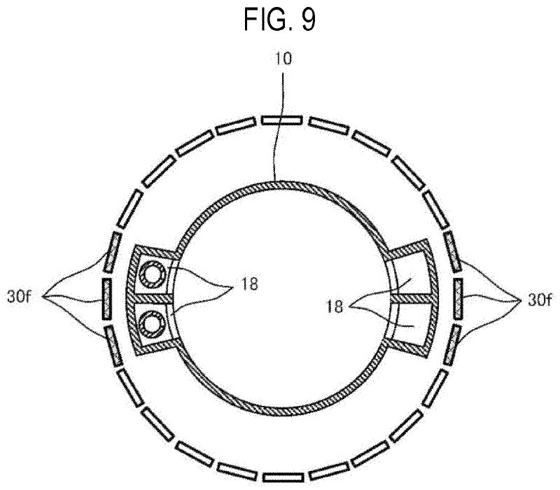

Further, in the example of FIG. 8, a form in which the wavelength characteristics of the radiated wave in the vicinity of the nozzle arrangement location and in the other locations are different is shown, but the present disclosure is not necessarily limited thereto. For example, as shown in FIG. 9, when the process tube 10 is provided with a buffer chamber 18 serving as a gas supply path, it is also feasible to make the wavelength characteristics of a radiation control body 30f arranged at a location corresponding to the buffer chamber 18 different from those at other locations.

Further, in the above-described arrangement examples (see FIGS. 7 to 9), a form in which the wavelength characteristics of the radiation control bodies 30b to 30f are different depending on the arrangement location is shown. However, as will be described below, it is also feasible to make the material of which the process tube 10 is made, partially different according to the respective wavelength characteristics.

The type of quartz (also referred to as “quartz glass”) of which the process tube 10 is made is broadly divided into molten quartz glass, which is made by melting natural quartz at a high temperature, and synthetic quartz glass made from chemically synthesized high-purity raw materials. The molten quartz glass is classified into oxyhydrogen molten glass by oxyhydrogen flame as a heat source for melting, and electric molten glass by electricity. Since the oxyhydrogen molten glass is melted by oxyhydrogen flame that generates water, it contains an OH group inside the glass, but the electric molten glass does not contain an OH group. The synthetic quartz glass has a higher purity than the molten quartz glass. For example, if it utilizes a flame hydrolysis reaction, it is classified into direct method synthetic glass, which is obtained by hydrolyzing silicon tetrachloride (SiCl₄) by a direct method (Verneuil method), and VAD method synthetic glass, which is obtained by hydrolyzing SiCl₄ by a soot method (VAD method). The VAD method synthetic glass has a lower OH group content than the direct method synthetic glass.

The quartz glass has different various characteristics such as light transmittance, depending on the type of quartz glass. For example, since the oxyhydrogen molten glass and the direct method synthetic glass containing a large amount of OH groups contain OH groups, they have a property of absorbing light of a wavelength in the vicinity of 2.2 to 2.7 μm. On the other hand, the electric molten glass and the VAD method synthetic glass do not have the property of absorbing light in such a wavelength range because of their low OH group content.

Based on the above, for the process tube 10, the type of quartz glass of which the process tube 10 is made may be partially different so that different characteristics can be exhibited at each location. For example, in the case of the arrangement example shown in FIG. 8, a portion near the arrangement location of the nozzle 17 (that is, a portion arranged at the position facing the radiation control body 30d) is made of the oxyhydrogen molten glass and direct method synthetic glass containing a large amount of OH groups, and the other portions (that is, portions arranged at the position facing the radiation control body 30e) are made of the electric molten glass and VAD method synthetic glass having low OH group content. By doing so, in the portion near the arrangement location of the nozzle 17, not only a wavelength of larger than 4 μm but also a wavelength of 4 μm or less, particularly a wavelength near 2.2 to 2.7 μm, is absorbed by the quartz of which the process tube 10 is made. Therefore, a portion of the process tube 10 near a nozzle arrangement location is heated more efficiently, which is very suitable for preheating a gas flowing through the nozzle 17 by using the heat.

### (9) Effects of the Present Embodiment

According to the present embodiment, one or more effects set forth below may be achieved.

(a) In the present embodiment, the radiation control body 30 is arranged between the process tube 10 and the heating heater 22, and the radiation control body 30 radiates a radiant wave in a wavelength band, which is different from that of the radiation heat from the heating heater 22, to the process tube 10. That is, the heat radiation control is performed by the radiation control body 30 between the process tube 10 and the heating heater 22.

Therefore, according to the present embodiment, it is possible to efficiently cause the radiant wave in the wavelength band absorbed by the wafer 2 to reach the wafer 2 without raising the temperature of the process tube 10 more than necessary. When the temperature rise of the process tube 10 itself is suppressed, there is no adverse effect due to the high temperature of the process tube 10. Further, for example, even when the heating heater 22 is a resistance heating heater, it is possible to efficiently cause the radiant wave to reach the wafer 2, thereby realizing the rapid temperature rise of the wafer 2. Moreover, it is easily possible to realize precise control so that the wafer 2 reaches a set temperature after the temperature rise of the wafer 2.

That is, in the present embodiment, by controlling the radiation intensity in a wavelength-selective manner by the radiation control body 30, it is possible to achieve the low cost and long life of the heating heater 22 and further achieve both the improvement of temperature rise performance in a low temperature range (for example, less than 400 degrees C.) and the maintenance of stable performance (the elimination of deviation) in a medium temperature range (for example, 400 degrees C. or higher, and lower than 650 degrees C.).

Therefore, according to the present embodiment, even if the wavelength of the radiant wave from the heating heater 22, the wavelength transmitted through the process tube 10, and the wavelength absorbed by the wafer 2 which is the objects to be processed are different from each other, the processing for the wafer 2 can be performed efficiently and appropriately.

(b) In the present embodiment, the radiation control body 30 is formed as a strip-shaped plate, and is suspended and supported by the holder 32 so as to surround the circumference of the process tube 10. That is, the radiation control body 30 is arranged between the process tube 10 and the heating heater 22 in a state of being separated from the heating heater 22. Therefore, the radiation control body 30 can be arranged with a very simple configuration. For example, it is possible to easily cope with the case where the radiation control body 30 is additionally arranged in the wafer heating structure in the existing device. Further, if the radiation control body 30 is configured to be able to be attached/detached, it is possible to easily cope with the case where the radiation control body 30 is replaced as needed.

(c) As described in the present embodiment, when the radiation control body 30 is arranged between the process tube 10 and the heating heater 22 so that the distance from the heating heater 22 is closer than the distance from the process tube 10, the radiation control body 30 can be efficiently heated, and it is also preferable for cooling the process tube 10 by the cooler.

(d) As described in the present embodiment, if a clearance of the radiation control body 30 to the heating heater 22 is set so that the radiation control body 30 does not interfere with the heating heater 22 even if thermal expansion occurs due to the heating from the heating heater 22, interference between the radiation control body 30 and the heating heater 22 does not occur even when in a high temperature state (for example, about 700 degrees C.) during the heat radiation control. Therefore, it is possible to prevent a situation in which the heat radiation control is hindered.

(e) As described in the present embodiment, when the cooler for flowing the cooling gas is provided at the vicinity of an outer peripheral surface of the process tube 10, it is more effective in suppressing the temperature rise of the process tube 10. When the temperature rise of the process tube 10 can be suppressed, the reaction products and the like adhering to the inner wall of the process tube 10 can be reduced, and as a result, it is possible to extend a cleaning cycle and a replacement cycle of the process tube 10.

(f) As described in the present embodiment, when the plurality of radiation control bodies 30 arranged between the process tube 10 and the heating heater 22 have different wavelength characteristics of the radiant wave radiated to the process tube 10, depending on the respective arrangement locations, it is very suitable for efficiently and appropriately heating the radiation control body 30.

For example, when the radiation control body 30b corresponding to the arrangement region 36 of the wafer 2 and the radiation control body 30c corresponding to the non-arrangement region 37 of the wafer 2 have different wavelength characteristics, the wafer 2 can be efficiently heated, and the WTW and WIW temperature deviations can be prevented from occurring in a temperature range of, for example, 400 degrees C. or higher.

Further, for example, when the radiation control body 30d arranged at a location corresponding to the gas supply path and the radiation control body 30e arranged at other locations have different wavelength characteristics, a gas flowing through the gas supply path can be preheated, and therefore, it is feasible to improve the efficiency and appropriateness of the processing for the wafer 2 using the gas.

(g) In the present embodiment, the radiation control body 30 includes the MIM lamination part M, and has a larger radiation rate in a narrow band wavelength of 4 μm or less and a smaller radiation rate in a wavelength of larger than 4 μm. Therefore, it is very suitable for radiating the radiant wave of the wavelength transmitted through the process tube 10 to reach the wafer 2 in the process tube 10.

### Second Embodiment

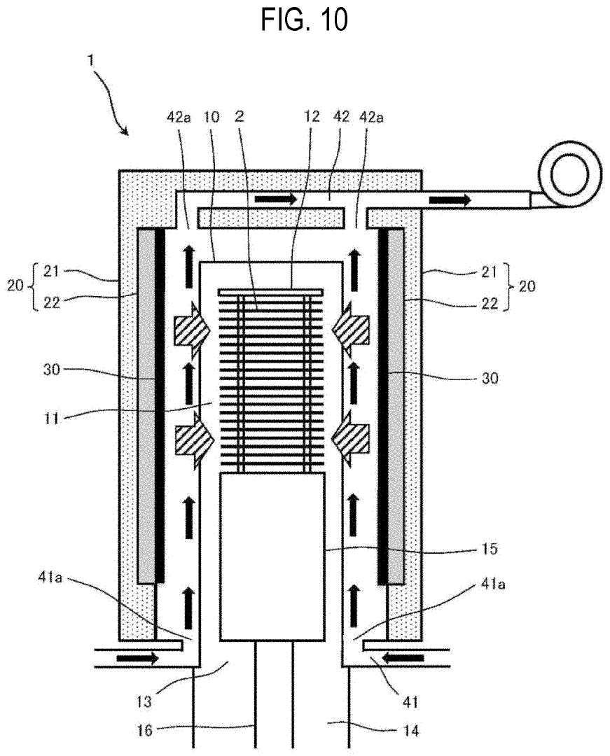

Next, a second embodiment of the present disclosure will be specifically described. Here, differences from the first embodiment described above will be mainly described. FIG. 10 is a side sectional view schematically showing a schematic configuration example of a semiconductor manufacturing apparatus according to a second embodiment.

In the semiconductor manufacturing apparatus 1 shown in FIG. 10, the radiation control body 30 is attached to the heating heater 22 so as to cover the heat generating surface of the heating heater 22 in the heater 20.

The radiation control body 30 is formed by laminating, for example, the heat radiation layer N described in the above-described first embodiment on the heat generating surface of the heating heater 22. That is, this radiation control body 30 is configured by replacing the substrate K described in the above-described first embodiment with the heat generating surface of the heating heater 22.

Even in a heating structure of the second embodiment using the radiation control body 30 having such a configuration, it is possible to efficiently and appropriately perform the processing for the wafer 2, as in the above-described first embodiment. Further, as in the above-described first embodiment, it is needless to say that the second embodiment includes a configuration in which the radiation control body 30 (the heat radiation layer N) is not provided at the height position corresponding to the heat insulating plate region below the substrate arrangement region. In particular, in the second embodiment, the heating target is different between the substrate arrangement region and the heat insulating plate region, and therefore, it is possible to change the heat radiation layer N to form the radiation control body 30. In addition to no cost and labor used to make the radiation control body 30 (the heat radiation layer N), due to the absence of the radiation control body 30, the radiant wave including a wavelength absorbed by the quartz member is radiated, thereby further improving the heating efficiency of the heat insulating plate region.

Further, in the second embodiment, since a heat radiation control function by the radiation control body 30 is installed incidentally to the heating heater 22, it is possible to realize the heat radiation control with the minimized structural change as compared with the above-described first embodiment. Therefore, as compared with the case where the radiation control body 30 separate from the heating heater 22 is used as in the above-described first embodiment, it is possible to reduce the cost for heat radiation control, and it is also possible to reduce the heat capacity of the heating structure.

### Modifications

The embodiments of the present disclosure have been specifically described above, but the present disclosure is not limited to the above-described embodiments, and various changes can be made without departing from the gist thereof

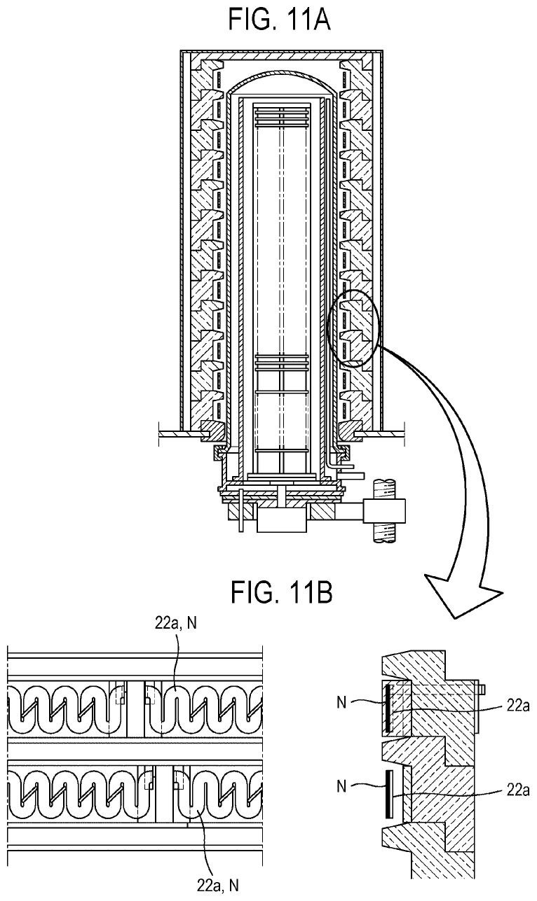

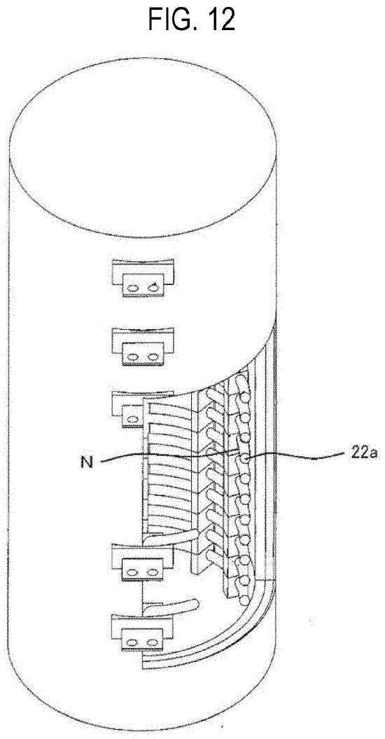

For example, the radiation control body 30 may be configured to be provided directly on a heating wire (heater wire) of the heating heater 22. Specifically, as shown in FIGS. 11A, 11B or 12, the heat radiation layer N is formed on the surface of the heating wire 22a of the heating heater. For example, the heat radiation layer N may be formed to cover both the surface of the heating wire 22a on the reaction tube side and the surface of the heating wire 22a on the heater heat insulating material side, or the surface of the heating wire 22a on the reaction tube side. This configuration can provide the following effects.

(1) Since a film-formed plate itself generates heat and raises the temperature, the temperature rise rate is faster than that of an indirect heating plate material addition structure.

(2) Since the member for the plate material is eliminated, the heat capacity is reduced as much. As a result, the temperature responsiveness at the time of raising and lowering the temperature is better than that of the plate material addition structure.

(3) Since the direct film-forming structure requires a smaller number of parts than the plate material addition structure, the parts cost and the processing cost can be reduced, and therefore, the heater can be manufactured at a relatively low cost.

Further, when a film is formed on one side facing an object to be heated and not on the other side, heat dissipation of the heater itself can be promoted to improve the responsiveness of the heater. For the film formation on one side of the heating wire 22a, not only the cost reduction but also the responsiveness of the heating wire 22a itself can be expected to be improved.

In the above-described embodiments, a case where the film-forming process is performed on the wafer 2 is taken as an example as a process of manufacturing a semiconductor device, but the type of film to be formed is not particularly limited. For example, it is suitable for application in a case of performing a film-forming process of a metal compound (W, Ti, Hf, etc.), a silicon compound (SiN, Si, etc.), or the like. Further, the film-forming process includes, for example, a CVD, a PVD, a process of forming an oxide film or a nitride film, a process of forming a film containing metal, and the like.

Further, the present disclosure is not limited to the film-forming process, but, in addition to the film-forming process, may also be applied to other substrate processing such as heat treatment (annealing process), plasma process, diffusion process, oxidation process, nitridation process, and lithography process as long as they are performed by heating an object to be processed, containing a semiconductor.

Further, in the above-described embodiments, the semiconductor device manufacturing apparatus and the method of manufacturing the semiconductor device used in the semiconductor manufacturing process have been mainly described, but the present disclosure is not limited thereto. For example, the present disclosure is also applicable to an apparatus for processing a glass substrate such as a liquid crystal display (LCD) device, and a method of manufacturing the same.

According to the present disclosure in some embodiments, it is possible to efficiently and appropriately perform a process on an object to be processed, including a semiconductor.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An apparatus for manufacturing a semiconductor device, comprising:
a reaction container in which an object to be processed, including a semiconductor, is arranged;
a heater configured to emit heat; and
a radiation control body arranged between the reaction container and the heater,
wherein the radiation control body is configured to radiate a radiant wave of a wavelength transmittable through the reaction container by selecting a wavelength of a radiation heat from the heater such that the radiant wave reaches the object to be processed in the reaction container.

2. The apparatus of claim 1, wherein the radiation control body is formed as a strip-shaped plate interposed between the reaction container and the heater.

3. The apparatus of claim 2, further comprising a holder configured to suspend and support the radiation control body.

4. The apparatus of claim 3, further comprising a plurality of radiation control bodies including the radiation control body,
wherein the holder has an annular portion having a shape corresponding to the reaction container, and
wherein the plurality of radiation control bodies suspended and supported by the annular portion are arranged to surround a circumference of the reaction container.

5. The apparatus of claim 4, wherein the plurality of radiation control bodies are arranged between the reaction container and the heater so that a distance from the heater is closer than a distance from the reaction container.

6. The apparatus of claim 5, wherein the holder is set with a clearance of the radiation control body to the heater so that the radiation control body does not interfere with the heater even if thermal expansion occurs due to heating from the heater.

7. The apparatus of claim 1, further comprising a cooler including an introduction part that introduces a cooling gas between the reaction container and the heater, and an exhauster that exhausts the introduced cooling gas.

8. The apparatus of claim 7, wherein the introduction part and the exhauster are arranged in the cooler so that the cooling gas flows in a vicinity of an outer peripheral surface of the reaction container along the reaction container.

9. The apparatus of claim 3, wherein a longitudinal length of the radiation control body is shorter than a tube length of the reaction container,
wherein the apparatus comprises a plurality of holders arranged in a plurality of stages along a tube length direction of the reaction container, and
wherein the holder in each stage suspends and supports the radiation control body, so that a plurality of radiation control bodies including the radiation control body are arranged side by side in the tube length direction of the reaction container.

10. The apparatus of claim 1, wherein the radiation control body is attached to the heater to cover a heat generating surface of the heater.

11. The apparatus of claim 4, wherein the plurality of radiation control bodies are configured so that wavelength characteristics of the radiant wave radiated to the reaction container differ depending on an arrangement location.

12. The apparatus of claim 9, wherein an arrangement region and a non-arrangement region of the object are formed in the reaction container, and
wherein the plurality of radiation control bodies are configured so that the radiation control body suspended and supported by a stage corresponding to the arrangement region and the radiation control body suspended and supported by a stage corresponding to the non-arrangement region have different wavelength characteristics of the radiant wave radiated to the reaction container.

13. The apparatus of claim 4, wherein a gas supply path is formed in the reaction container, and
wherein the plurality of radiation control bodies are configured so that the radiation control body arranged at a location corresponding to the gas supply path and the radiation control body arranged at other locations have different wavelength characteristics of the radiant wave radiated to the reaction container.

14. A method of manufacturing a semiconductor device, comprising:
arranging an object to be processed, containing a semiconductor, in a reaction container; and
heating the object in the reaction container by using a heater that emits heat to the reaction container, in a state where a radiation control body is interposed between the reaction container and the heater,
wherein the radiation control body radiates a radiant wave of a wavelength transmittable through the reaction container by selecting a wavelength of a radiation hear from the heater such that the radiant wave reaches the object to be processed in the reaction container.
